(19) United States
(12) Patent Application Publication
(10) Pub. No.: US 2007/0122653 A1
(43) Pub. Date: May 31, 2007

(54) Phosphorescent electroluminescent element

(75) Inventors: Esther Breuning, Niedernhausen (DE); Anja Gerhard, Darmstadt (DE); Horst Vestweber, Gilersberg-Winterscheid (DE); Philipp Stoessel, Frankfurt am Main (DE)

Correspondence Address: CONNOLLY BOVE LODGE & HUTZ, LLP, P O BOX 2207, WILMINGTON, DE, 19899, US

(73) Assignee: Merck Patent GmbH, Darmstadt (DE)

(21) Appl. No.: 10/588,918

(22) PCT Filed: Feb. 10, 2005
(86) PCT No.: PCT/EP05/01313

§ 371 Date: Aug. 9, 2006

(30) Foreign Application Priority Data
Feb. 10, 2004 (DE) 10 2004 006 622.1

(51) Int. Cl. H01L 51/54

(52) U.S. Cl. 428/690; 428/917; 313/504; 313/506; 257/102; 257/103; 257/E51.044

(57) ABSTRACT

The present invention describes electroluminescent elements comprising cathode and anode and at least one emission layer, where this comprises at least one matrix material A comprising certain elements and at least one emitter layer B which emits light from the triplet state.

In a series of different applications which can be ascribed to the electronics industry in the broadest sense, the use of organic semiconductors as functional materials has been reality for some time or is expected in the near future. The use of semi-conducting organic compounds which are capable of the emission of light in the visible spectral region is just at the beginning of the market introduction, for example in organic electroluminescent devices (OLEDs). For simpler devices, the market introduction of OLEDs has already taken place, as confirmed by the car radios from Pioneer or a digital camera from Kodak with an “organic display”. Nevertheless, there is still a great demand for technical improvement.

A more recent development is the use of organometallic complexes which exhibit phosphorescence (=triplet emission) instead of fluorescence (=singlet emission) (M. A. Baldo et al., Appl. Phys. Lett. 1999, 75, 4-6). For quantum-mechanical reasons, an up to four-fold increase in the quantum, energy and power efficiency is possible using emitters of this type. However, corresponding device compositions which are also able to implement these advantages in OLEDs have to be found for this purpose. Essential conditions for practical use that should be mentioned here are, in particular, efficient energy transfer to the triplet emitter and thus efficient emission, a long operating lifetime and a low use and operating voltage.

The general structure of organic electroluminescent devices is described, for example, in U.S. Pat. No. 4,539,507, U.S. Pat. No. 5,151,629, and in EP 01202358. The emission layer in phosphorescent devices usually consists of phosphorescent dyes, for example tris(phenylpyridyl)iridium (Ir(PPy)₃), which are doped into matrix materials. This matrix material has a particular role: it must facilitate or improve charge transport and/or charge carrier recombination of holes and/or electrons and, where appropriate, transfer the energy produced on recombination to the emitter. This job has to date predominantly been taken on by matrix materials based on carbazole, such as 4,4′-bis(carbazol-9-yl)biphenyl (CBP). In addition, ketones and imines (WO 04/093207) and phosphine oxides, sulfoxides, sulfones, etc., have recently been described as matrix materials (unpublished application DE 10330761.3).

Matrix materials based on carbazole have some disadvantages in practice. These are, inter alia, the frequently short lifetime of the devices and the frequently high operating voltages, which result in low power efficiencies. Furthermore, it has been found that CBP is unsuitable for blue-emitting electroluminescent devices, which results in poor efficiencies. In addition, the construction of the devices comprising CBP is very complex since a hole-blocking layer and an electron-transport layer additionally have to be used. If these additional layers are not used, as described, for example, by Adachi et al. (Organic Electronics 2001, 2, 37), good efficiencies are observed, but only at extremely low brightnesses, while the efficiency at higher brightness, as is necessary for use, is more than an order of magnitude lower. Thus, high voltages are required for high brightnesses, meaning that the power efficiency, in particular in passive matrix applications, is very low here.

WO 00/057676 mentions matrix materials from the group of the metal complexes of quinoxolates, oxadiazoles and triazoles, where no advantages of these matrix materials over other materials are mentioned and the only example mentioned is Alq₃ (tris(hydroxyquinolinato)aluminium).

WO 04/095598 describes tetraaryl compounds of the elements carbon, silicon, germanium, tin, lead, selenium, titanium, zirconium and hafnium as matrix materials for triplet emitters.

There are still considerable problems in OLEDs which require urgent improvement:
1. Thus, in particular, the operating lifetime of OLEDs is still short, meaning that it has hitherto only been possible to implement simple applications commercially.
2. Although the efficiencies of OLEDs are acceptable, improvements are, however, still desired here—especially for mobile applications.
3. The operating voltage required is high, especially in efficient phosphorescent OLEDs, and therefore has to be reduced in order to improve the power efficiency. This is of major importance, in particular, for mobile applications.
4. The variety of layers makes the construction of OLEDs complex and technologically very complicated. This applies in particular to phosphorescent OLEDs, in which, in addition to the other layers, a hole-blocking layer also has to be used. It would therefore be very advantageous to be able to achieve OLEDs having a simpler structure with fewer layers, but still with good or improved properties.

These reasons make improvements in the production of OLEDs necessary.

Surprisingly, it has now been found that the use of certain matrix materials in combination with triplet emitters results in significant improvements over the prior art, in particular in relation to the efficiency, in combination with a greatly increased lifetime and reduced operating voltage. In addition, these matrix materials enable a significantly simplified layer structure of the OLED since it is not necessary either to use a separate hole-blocking layer or a separate electron-transport and/or electron-injection layer. Depending on the material, a separate hole-transport layer may also be omitted, which likewise represents a significant technological advantage. The presence of at least one element having an atomic number ≧15 is necessary here for efficient energy transfer.

The invention relates to organic electroluminescent devices comprising cathode and anode and at least one emission layer, characterised in that the emission layer
comprises at least one matrix material A, which comprises at least one element having an atomic number ≧15, with the proviso that the matrix material comprises none of the elements Si, Ge, Sn, Pb, Al, Ga, In or Tl and is not a noble-gas compound, furthermore with the proviso that matrix materials A having the partial-structure L=X are excluded, where L stands for a substituted C, P, As, Sb, Bi, S, Se or Te and X has at least one non-bonding electron pair, with the proviso that tetraaryl compounds of the elements Se, Ti, Zr and Hf are excluded, and with the proviso that metal complexes of the quinoxolates, oxadiazoles and triazoles are excluded as matrix material;
   and
comprises at least one emission material B which emits light, preferably in the visible region, on suitable excitation from the triplet state and comprises at least one element having an atomic number of greater than 20.

The symbol “=” used above stands for a double bond in the sense of the Lewis notation. X may, for example, stand for substituted O, S, Se or N.

The lowest triplet energy of the matrix materials is preferably between 2 and 4 eV. The lowest triplet energy is defined here as the energy difference between the singlet ground state and the lowest triplet state of the molecule. The triplet energy can be determined by various spectroscopic methods or by quantum-chemical calculation. This triplet state has proven favourable since the energy transfer of the matrix material to the triplet emitter then proceeds very efficiently and thus results in high efficiency of the emission from the triplet emitter. A triplet energy of <2 eV is generally not sufficient for efficient energy transfer, even for red-emitting triplet emitters. Preference is given to matrix materials A whose triplet energy is greater than the triplet energy of the triplet emitter B used. The triplet energy of the matrix material A is preferably at least 0.1 eV greater than that of the triplet emitter B, in particular at least 0.5 eV greater than that of the triplet emitter B.

In order to ensure high thermal stability of the display, preference is given to amorphous matrix materials A whose glass transition temperature T_{g} (measured as the pure substance) is greater than 90° C., particularly preferably greater than 110° C., in particular greater than 130° C.

In order that the materials are stable during the vapour-deposition process, they should preferably have high thermal stability, preferably greater than 200° C., particularly preferably greater than 300° C.

The matrix material A preferably comprises uncharged compounds. These are preferred to salts since they can generally be evaporated more easily or at lower temperature than charged compounds, which form ionic crystal lattices. In addition, salts have an increased tendency towards crystallisation, which counters the formation of glass-like phases.

The matrix material A furthermore preferably comprises defined molecular compounds.

In order to prevent electron transfer between the matrix material and the triplet emitter in the ground state, it is preferred for the LUMO (lowest unoccupied molecular orbital) of the matrix material A to be higher than the HOMO (highest occupied molecular orbital) of the triplet emitter B. For the same reason, it is preferred for the LUMO of the triplet emitter B to be higher than the HOMO of the matrix material A.

The compound of the emission layer having the higher (less negative) HOMO is principally responsible for the hole current. It is preferred here for the HOMO of this compound, irrespective of whether it is the matrix material A or the triplet emitter B, to be in the region of ±0.5 eV of the HOMO of the hole-transport layer or hole-injection layer or anode (depending on which of these layers is directly adjacent to the emission layer). The compound in the emission layer having the lower (more negative) LUMO is principally responsible for the electron current. It is preferred here for the LUMO of this compound, irrespective of whether it is the matrix material A or the triplet emitter B, to be in the region of ±0.5 eV of the LUMO of the hole-blocking layer or electron-transport layer or cathode (depending on which of these layers is directly adjacent to the emission layer).

The charge-carrier mobility of the emission layer is preferably between 10⁻⁸ and 10⁻¹ cm²V·s under the field strengths arising in the OLED.

The position of the HOMO or LUMO can be determined by various methods, for example by solution electrochemistry, for example cyclic voltammetry, or by UV photoelectron spectroscopy. In addition, the position of the LUMO can be calculated from the HOMO determined electrochemically and the band separation determined optically by absorption spectroscopy.

Preference is furthermore given to materials which are predominantly stable during electron transfer (oxidation and/or reduction), i.e. exhibit predominantly reversible reduction or oxidation. Thus, electron-conducting materials should, in particular, remain stable during reduction and hole-conducting materials during oxidation. “Stable” or “reversible” here means that the materials exhibit little or no decomposition or chemical changes, such as rearrangement, during reduction or oxidation.

The HOMO or LUMO position of the matrix materials can be adapted over a broad range to the respective conditions in the device and thus optimised. Thus, they can be shifted by chemical modification. This is possible, for example, by variation of the central atom with retention of the ligand system or the substituents or by introduction of other, in particular electron-donating or electron-withdrawing substituents onto the ligand. The person skilled in the art is able to adjust the properties of the matrix for each triplet emission material in such a way that ideal emission properties are obtained overall.

Furthermore, matrix materials A which have a dipole moment other than zero have proven particularly favourable. In the case of materials which comprise a plurality of identical molecular fragments, however, the overall dipole moment may also be extinguished. For this reason, it is not the overall dipole moment that will be considered in this invention for the determination of preferred matrix materials in such cases, but instead the dipole moment of the molecular fragment (i.e. the part of the molecule) around the element having an atomic number ≧15. Preference is given to a dipole moment of the matrix materials A (or of the molecular fragment around the element having an atomic number ≧15) of ≧1 D, particularly preferably ≧1.5 D. The dipole moment can be determined here by quantum-chemical calculation.

The matrix material A can be either organic or inorganic. It may also comprise organometallic compounds or coordination compounds, where the metals can be either main-group or transition metals or lanthanoids, and the compounds can be either monocyclic or polycyclic. For the purposes of this application, an organometallic compound is a compound which has at least one direct metal-carbon bond.

For the purposes of this application, a coordination compound is a metal complex containing no direct metal-carbon bond, where the ligands can be organic, but also purely inorganic ligands.

As stated above, suitable matrix materials A are compounds which have at least one element having an atomic number ≧15, but none of the elements Si, Ge, Sn, Pb, Al, Ga, In or Tl, and which are not tetraaryl compounds of the elements Se, Ti, Zr or Hf. For practical considerations, noble-gas compounds (unstable or low-melting compounds) are likewise excluded. Compounds of radioactive elements are not preferred as matrix material for health reasons. Suitable materials may be compounds of the main-group elements and compounds of the subgroup elements. Suitable matrix materials of the main-group elements may thus be compounds of the alkali metals potassium, rubidium or caesium, furthermore compounds of the alkaline earth metals calcium, strontium or barium, compounds of the heavier elements of main group 5 (group 15 according to IUPAC), i.e. phosphorus, arsenic, antimony or bismuth, compounds of the heavier elements of main group 6 (group 16 according to IUPAC), i.e. sulfur, selenium or tellurium, or compounds of the halogens chlorine, bromine or iodine. In the case of the compounds of main groups 5 and 6, organo-molecular compounds are particularly suitable. Also suitable are compounds of the subgroup elements, i.e. transition-metal compounds (compounds of the elements Sc, Y, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd or Hg) and lanthanoid compounds (compounds of the elements La, Ce, Pr, Nd, Sm, Eu, Gd, Tb, Dy, Ho, Er, Tm, Yb or Lu).

It may also be preferred here for the matrix material to contain two or more of the above-mentioned elements, which may be identical or different. In principle, suitable compounds here are those as described in Houben-Weyl, Methoden der Organischen Chemie [Methods of Organic Chemistry] (4th edition, Georg Thieme Verlag, Stuttgart, 1964) in volumes 9 (S, Se, Te), 12/1 and 12/2 (P), 13/1 (Li, Na, K, Rb, Cs, Cu, Ag, Au), 13/2a (Be, Mg, Ca, Sr, Ba, Zn, Cd), 13/2b (Hg), 13/7 (Pb, Ti, Zr, Hf, Nb, Ta, Cr, Mo, W), 13/8 (As, Sb, Bi), 13/9a (Mn, Re, Fe, Ru, Os, Pt), 13/9b (Co, Rh, Ir, Ni, Pd), and in the supplementary volumes E1 and E2 (P) and E12,b (Te) of 1982.

Preferred compounds are discrete molecular or coordinative compounds which also form discrete structures in the solid state. Less suitable are thus salts, coordination polymers, etc., since these can generally only be evaporated with difficulty or not at all. Salts are also less suitable owing to their tendency towards crystallisation. For processing from solution, the compounds must be soluble in solvents in which the triplet emitter is also soluble.

Preference is given to compounds of the transition metals and compounds of the elements of main groups 5, 6 and 7; particular preference is given to compounds of the transition metals and compounds of the elements of main groups 5 and 6.

Suitable compounds of the elements of main group 5 (phosphorus, arsenic, antimony and bismuth) are preferably organophosphorus compounds and the corresponding arsenic, antimony and bismuth compounds.

Particularly suitable here are aromatic or aliphatic phosphines or phosphites and the corresponding As, Sb and Bi compounds. Organic phosphorus halides or hydroxides (and the corresponding As, Sb and Bi compounds) are also possible, where, in particular, the alkyl compounds are in some cases pyrophoric and are therefore not preferred. Likewise suitable are compounds containing an element-element multiple bond, phospha- and arsa-aromatic compounds (for example phospha- and arsa-benzene derivatives) and unsaturated five-membered rings (for example phosphol and arsol). Furthermore suitable are phosphoranes (pentavalent phosphorus compounds) and pentavalent organoarsenic compounds and corresponding pentavalent organoarsenic halides or hydroxides (and the corresponding Sb and Bi compounds), where the thermal stability falls with increasing halogen content and these compounds are therefore less preferred.

Preference is furthermore given to phosphorus sulfides which contain no phosphorus-sulfur double bond, such as, for example, P₄S₃, P₄S₄ or P₄S₅.

Suitable compounds of the elements of main group 6 (sulfur, selenium and tellurium) are, in particular, organosulfur compounds (or the corresponding selenium and tellurium compounds), such as aromatic or aliphatic thiols (or corresponding selenium and tellurium compounds), organosulfur halides (or corresponding selenium and tellurium compounds), aromatic or aliphatic thioethers (or seleno- or telluroethers) or aromatic or aliphatic disulfides (or diselenides or ditellurides). Preference is furthermore given to sulfur-containing aromatic compounds, such as, for example, derivatives of thiophene, benzothiophene or dibenzothiophene (or the corresponding selenium and tellurium compounds), such as, for example, derivatives of selenophene, tellurophene, etc.).

Suitable compounds of the halogens are, for example, organic halogen compounds, but also compounds in which chlorine, bromine or iodine is bonded to the above-mentioned elements, for example to S, Se, Te, P, As, Sb or Bi, where these are not preferred owing to the high hydrolysis sensitivity.

Particularly preferred matrix materials are compounds containing at least one element of main group 5 or 6 which is substituted by at least one substituted or unsubstituted, aromatic or heteroaromatic ring system having 3 to 60 C atoms, in particular those in which all substituents on the element of main group 5 or 6 are aromatic or heteroaromatic ring systems having 3 to 60 C atoms, of the formula (A) or formula (B) 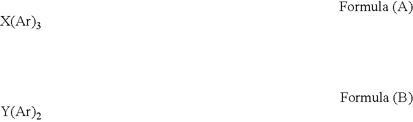
where the following applies to the symbols used:
X is on each occurrence P, As, Sb or Bi, preferably P or As, particularly preferably P;
Y is on each occurrence S, Se or Te, preferably S or Se, particularly preferably S;
Ar is on each occurrence, identically or differently, an aromatic or heteroaromatic ring system having 3 to 60 C atoms, which may be substituted by F or organic radicals having 1 to 40 C atoms, preferably an aromatic ring system having 6 to 40 C atoms.

In a preferred embodiment of the invention, Ar stands for phenyl, biphenyl, terphenyl, naphthyl, anthryl, phenanthrenyl, pyryl, fluorenyl, spirobifluorenyl, dihydro-phenanthrenyl, tetrahydropyrenyl or a combination of 2 or 3 of these systems. Particularly preferably, at least one of the radicals Ar stands for fluorenyl or spirobifluorenyl, very particularly preferably, all radicals Ar stand for fluorenyl or spirobifluorenyl.

In the case of the compounds of the transition-metal elements, as in the case of the compounds of the lanthanoids, the alkali and alkaline earth metals, three substance classes are in principle possible: organometallic compounds, organic coordination compounds and purely inorganic metal complexes. In the case of the metal compounds, preference is given to compounds of the transition-metal elements. These may each contain one or more metal atoms, or even metal clusters. In polynuclear metal complexes, the metals may be connected by bridging ligands and/or also by direct metal-metal bonds. It should be expressly pointed out at this point that compounds which can also be used as triplet emitters in another connection may very well also be suitable and preferred as matrix material here. Thus, for example, a green-emitting triplet emitter, such as, for example, tris(phenylpyridyl)iridium(III) (IrPPy), may also be a good matrix material for a red-emitting triplet emitter and may result in highly efficient red emission in this combination.

A review of organometallic compounds can be found, for example, in Comprehensive Organometallic Chemistry: The Synthesis, Reactions and Structures of Organometallic Compounds, Volumes 1-9, Wilkinson Ed., Pergamon Press, Oxford, 1982, in Comprehensive Organometallic Chemistry—II, Volumes 1-14, Abel Ed., Pergamon Press, Oxford, 1995 and in Elschenbroich, Salzer, Organometalichemie[Organometallic Chemistry], Teubner Studienbücher, Stuttgart, 1993. A review of non-organometallic metal complexes can be found, for example, in Hollemann, Wiberg, Lehrbuch der Anorganischen Chemie [Textbook of Inorganic Chemistry], Walterde Gruyter, Berlin, 1985, in Huheey, Keiter, Keiter, Inorganic Chemistry, Harper Collins, New York, 1993 and in Comprehensive Coordination Chemistry.

Preference may also be given to compounds which may contain two or more elements having an atomic number ≧15, which may be identical or different, such as, for example, halogenated main-group element compounds, polynuclear metal complexes, metal complexes with phosphine or halogen ligands, etc. It is furthermore likewise preferred to use mixtures of two or more matrix materials A which meet the above-mentioned conditions.

In order to be used as functional material, the matrix materials A together with the emitters B are applied in the form of a film to a substrate by generally known methods which are familiar to the person skilled in the art, such as vacuum vapour deposition, vapour deposition in a stream of carrier gas or also from solution by spin coating or using various printing processes (for example ink-jet printing, offset printing, LITI printing, etc.).

Depending on the processing, further requirements are made of the matrix materials A and the triplet emittesr B: if it is intended to produce the layer by vacuum vapour deposition, it is necessary that the materials are allowed to evaporate under reduced pressure without decomposition. This requires adequate volatility and high thermal stability of the materials. If it is intended to produce the layer from solution, for example by printing techniques, it is necessary that the materials have sufficiently high solubility, preferably ≧0.5%, in a suitable solvent or solvent mixture.

The above-described matrix materials A are used in combination with phosphorescence emitters B. The organic electroluminescent device thus produced comprises, as emitter B, at least one compound which emits light, preferably in the visible region, on suitable excitation and in addition contains at least one atom having an atomic number of greater than 20, preferably greater than 38 and less than 84, particularly preferably greater than 56 and less than 80.

The phosphorescence emitters B used are preferably compounds which contain molybdenum, tungsten, rhenium, ruthenium, osmium, rhodium, iridium, palladium, platinum, silver, gold or europium, in particular iridium or platinum.

Particularly preferred mixtures comprise, as emitter B, at least one compound of the formulae (1) to (4) 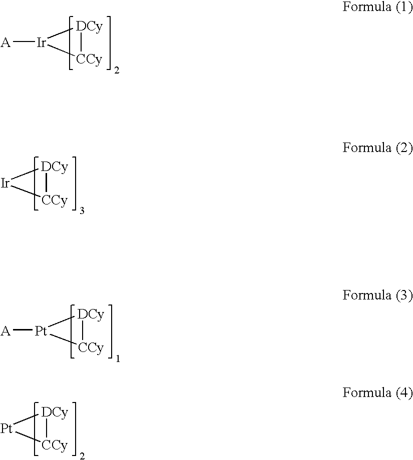
where the following applies to the symbols and indices used:
DCy is on each occurrence, identically or differently, a cyclic group which contains at least one donor atom, preferably nitrogen or phosphorus, via which the cyclic group is bonded to the metal and which may in turn carry one or more substituents R¹; the groups DCy and CCy are bonded to one another via at least one covalent bond;
CCy is on each occurrence, identically or differently, a cyclic group which contains a carbon atom via which the cyclic group is bonded to the metal and which may in turn carry one or more substituents R¹;
R¹ is on each occurrence, identically or differently, H, F, Cl, Br, I, NO₂, CN, a straight-chain, branched or cyclic alkyl or alkoxy group having 1 to 40 C atoms, in which one or more non-adjacent CH₂ groups may be replaced by —O—, —S—, —NR²— or —CONR²— and in which one or more H atoms may be replaced by F, or an aryl or heteroaryl group having 4 to 14 C atoms, which may be substituted by one or more non-aromatic radicals R¹; a plurality of substituents R¹ here, both on the same ring and also on the two different rings, may together in turn define a further mono- or polycyclic, aromatic or aliphatic ring system;
A is on each occurrence, identically or differently, a bidentate, chelating ligand, preferably a diketonate ligand,
R² is on each occurrence, identically or differently, H or an aliphatic or aromatic hydrocarbon radical having 1 to 20 C atoms;
   a plurality of the ligands here may also be linked via one or more substituents R¹ as bridging unit to form a larger polypodal ligand.

Examples of the emitters described above are given in the applications WO 00/70655, WO 01/41512, WO 02/02714, WO 02/15645, EP 1191613, EP 1191612, EP 1191614, WO 04/081017 and the unpublished application DE 10345572.8.

It may also be preferred here for the emission layer to comprise two or more triplet emitters B.

It may also be preferred for the emission layer to comprise one or more further compounds in addition to the at least one matrix material A and the at least one emitter B.

The emission layer of the organic electroluminescent device comprises 99 to 1% by weight, preferably 97 to 5% by weight, particularly preferably 95 to 50% by weight, in particular 93 to 80% by weight, of matrix compounds A, based on the total composition of the emission layer.

The emission layer furthermore comprises 1 to 99% by weight, preferably 3 to 95% by weight, particularly preferably 5 to 50% by weight, in particular 7 to 20% by weight, of emitter(s) B, based on the total composition of the emission layer.

In addition to the cathode, the anode and the emission layer, the organic electro-luminescent device may comprise further layers, such as, for example, hole-injection layer, hole-transport layer, hole-blocking layer, electron-transport layer and/or electron-injection layer. Each of these layers, but in particular the charge-injection and -transport layers, may also be doped. However, it should be pointed out at this point that each of these layers does not necessarily have to be present. Thus, it has been found, for example, that an OLED which comprises neither a separate hole-blocking layer nor a separate electron-transport layer may furthermore exhibit very good results in electroluminescence, in particular a significantly higher power efficiency still. This is particularly surprising since a corresponding OLED comprising a carbazole-containing matrix material without hole-blocking and electron-transport layers exhibits only very low power efficiencies (cf. Adachi et al., Organic Electronics 2001, 2, 37).

It has likewise been found that an OLED which does not comprise separate hole-transport and/or hole-injection layers may furthermore exhibit very good results in electroluminescence. This is the case, in particular, on use of hole-conducting matrix materials A.

The invention thus furthermore relates to an organic electroluminescent device according to the invention in which the emission layer is directly adjacent to the electron-transport layer without the use of a hole-blocking layer or is directly adjacent to the electron-injection layer or cathode without the use of a hole-blocking layer and an electron-transport layer.

The invention furthermore relates to an organic electroluminescent device according to the invention in which the emission layer is directly adjacent to the hole-injection layer without the use of a hole-transport layer or is directly adjacent to the anode without the use of a hole-transport layer and a hole-injection layer.

A further possible device structure comprises an emission layer according to the invention comprising matrix material A and triplet emitter B, characterised in that the doping zone of the emitter B in the matrix A perpendicular to the layer only extends over part of the matrix layer. This has already been described for other matrix materials in the unpublished application DE 10355381.9. In this device structure, the use of a separate hole-blocking layer is not necessary, and a separate electron-transport layer also does not necessarily have to be used.

The organic electroluminescent devices exhibit higher efficiency, a significantly longer lifetime and, in particular without the use of a hole-blocking layer and electron-transport layer, significantly lower operating voltages and higher power efficiencies than OLEDs in accordance with the prior art which use CBP as matrix material. The structure of the OLED is furthermore significantly simplified if a separate hole-blocking layer and/or electron-transport layer or a separate hole-transport layer and/or hole-injection layer is not used, which represents a considerable technological advantage.

The present application text is directed only to organic light-emitting diodes and the corresponding displays. In spite of this restriction of the description, it is possible for the person skilled in the art, without further inventive step, to use corresponding mixtures of matrix material A and triplet emitter B for other applications, in particular in OLED-near or related applications, such as, for example, organic solar cells (O-SCs), organic laser diodes (O-lasers), organic field-effect transistors (O-FETs), organic thin-film transistors (O-TFTs) and others.

### EXAMPLES

### Example 1

### Determination of Suitable Compounds by Quantum-Chemical Calculation

The electronic properties of some compounds were determined by quantum-chemical calculation. The geometries were optimised by means of a Hartree-Fock calculation (6-31g(d)). The HOMO and LUMO values and the dipole moment were determined by DFT (density functional theory) calculation (B3PW91/6-31g(d)). The triplet levels were determined by RPA (random phase approximation) (B3LYP/6-31+g(d)). All calculations were carried out using the Gaussian 98 software package. Some compounds whose quantum-chemical properties (although not necessarily the other properties, such as glass transition temperature, etc.) are suitable for triplet matrix materials are listed in Table 1.

TABLE 1
Calculated physical properties of some materials which are suitable
(on the basis of these properties) as triplet matrix materials

| | | | | Dipole |
|---|---|---|---|---|
| | HOMO | LUMO | Triplet energy | moment |
| Compound | [eV] | [eV] | [eV] | [D] |
| Triphenylphosphine | −6.06 | −1.86 | 3.62 | 1.51 |
| Diphenylmethylphosphine | −6.12 | −1.79 | 3.64 | 1.49 |
| Dimethylphenylphosphine | −6.27 | −1.74 | 3.81 | 1.47 |
| Diphenyl sulfide | −6.17 | −1.84 | 3.58 | 1.89 |
| Methyl phenyl sulfide | −6.37 | −1.80 | 3.80 | 1.94 |

1. Organic electroluminescent device comprising cathode and anode and at least one emission layer, characterised in that the emission layer
comprises at least one matrix material A, which comprises at least one element having an atomic number ≧15, with the proviso that the matrix material comprises none of the elements Si, Ge, Sn, Pb, Al, Ga, In or Tl, is not a noble-gas compound, furthermore with the proviso that matrix materials A having the partial-structure L=X are excluded, where L stands for a substituted C, P, As, Sb, Bi, S, Se or Te and X has at least one non-bonding electron pair, with the proviso that tetraaryl compounds of the elements Se, Ti, Zr and Hf are excluded, and with the proviso that metal complexes of the quinoxolates, oxadiazoles and triazoles are excluded as matrix material;
and
comprises at least one emission-capable emission material B which emits light on suitable excitation from the triplet state and comprises at least one element having an atomic number of greater than 20.

2. Organic electroluminescent device according to claim 1, characterised in that the matrix material A comprises a main-group element.

3. Organic electroluminescent device according to claim 2, characterised in that the matrix material A comprises phosphorus, arsenic, antimony and/or bismuth.

4. Organic electroluminescent device according to claim 2, characterised in that the matrix material A comprises sulfur, selenium and/or tellurium.

5. Organic electroluminescent element according to claim 3, characterised in that the element having an atomic number ≧15 is substituted by at least one substituted or unsubstituted, aromatic or heteroaromatic ring system having 3 to 60 C atoms.

6. Organic electroluminescent element according to claim 5, comprising, as matrix material A, at least one compound of the formula (A) or formula (B) 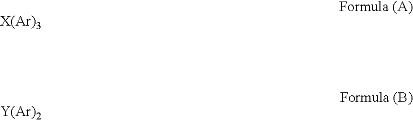
where the following applies to the symbols used:
X is on each occurrence P, As, Sb or Bi;
Y is on each occurrence S, Se or Te;
Ar is on each occurrence, identically or differently, an aromatic or heteroaromatic ring system having 3 to 60 C atoms, which may be substituted by F or organic radicals having 1 to 40 C atoms.

7. Organic electroluminescent element according to claim 6, characterised in that the aromatic ring system is phenyl, biphenyl, terphenyl, naphthyl, anthryl, phenanthrenyl, pyryl, fluorenyl, spirobifluorenyl, dihydrophenanthrenyl, tetrahydropyrenyl or a combination of 2 or 3 of these systems.

8. Organic electroluminescent device according to claim 1, characterised in that the matrix material A comprises at least one transition-metal element and/or a lanthanoid element.

9. Organic electroluminescent device according to claim 1, characterised in that the emission layer comprises a mixture of at least two of these matrix materials.

10. Organic electroluminescent device according to claim 1, characterised in that the triplet energy of the matrix material A is between 2 and 4 eV.

11. Organic electroluminescent device according to claim 1, characterised in that the triplet energy of the matrix material A is greater than the triplet energy of the triplet emitter B used.

12. Organic electroluminescent device according to claim 1, characterised in that the matrix material A is amorphous.

13. Organic electroluminescent device according to claim 12, characterised in that the matrix material A has a glass transition temperature T_{g} of greater than 90° C.

14. Organic electroluminescent device according to claim 1, characterised in that the matrix materials A are uncharged compounds.

15. Organic electroluminescent device according to claim 1, characterised in that the LUMO of the matrix material A is higher than the HOMO of the triplet emitter B and that the LUMO of the triplet emitter B is higher than the HOMO of the matrix material A.

16. Organic electroluminescent device according to claim 1, characterised in that the HOMO of the compound having the less negative HOMO in the emission layer is in the region of ±0.5 eV of the HOMO of the layer adjacent to the emission layer on the anode side.

17. Organic electroluminescent device according to claim 1, characterised in that the LUMO of the compound having the more negative LUMO in the emission layer is in the region of ±0.5 eV of the LUMO of the layer adjacent to the emission layer on the cathode side.

18. Organic electroluminescent device according to claim 1, characterised in that the dipole moment of the molecular fragment around the element having an atomic number ≧15 is other than zero.

19. Organic electroluminescent device according to claim 1, characterised in that the matrix materials A are discrete molecular or coordinative compounds which also form discrete structures in the solid state.

20. Organic electroluminescent device according to claim 1, characterised in that the matrix material A used is a compound which can itself also emit light from the triplet state.

21. Organic electroluminescent device according to claim 1, characterised in that the layers of matrix material A and triplet emitter B are applied to a substrate by vacuum vapour deposition, vapour deposition in a stream of carrier gas or from solution by spin coating or by means of printing processes.

22. Organic electroluminescent device according to claim 1, characterised in that the triplet emitter B comprises at least one atom having an atomic number of greater than 38 and less than 84.

23. Organic electroluminescent device according to claim 22, characterised in that the triplet emitter comprises at least one of the elements molybdenum, tungsten, rhenium, ruthenium, osmium, rhodium, iridium, palladium, platinum, silver, gold or europium.

24. Organic electroluminescent device according to claim 22, characterised in that a mixture of at least two triplet emitters B is used.

25. Organic electroluminescent device according to claim 1, characterised in that the emission layer comprises 1 to 99% by weight of one or more matrix compounds A and 99 to 1% by weight of one or more emitters B, based on the total composition of the emission layer.

26. Organic electroluminescent device according to claim 25, characterised in that the emission layer comprises 80 to 93% by weight of one or more matrix compounds A and 20 to 7% by weight of one or more emitters B, based on the total composition of the emission layer.

27. Organic electroluminescent device according to claim 1, characterised in that further layers are present in addition to the cathode, the anode and the emitter layer.

28. Organic electroluminescent device according to claim 27, characterised in that at least one hole-injection layer, which may also be doped, and/or at least one hole-transport layer, which may also be doped, and/or at least one hole-blocking layer and/or at least one electron-transport layer, which may also be doped, and/or at least one electron-injection layer, which may also be doped, is present.

29. Organic electroluminescent device according to claim 1, characterised in that the emission layer is directly adjacent to the electron-transport layer without the use of a hole-blocking layer or in that it is directly adjacent to the electron-injection layer or the cathode without the use of a hole-blocking layer and electron-transport layer.

30. Organic electroluminescent device according to claim 1, characterised in that the emission layer is directly adjacent to the hole-injection layer without the use of a hole-transport layer or in that it is directly adjacent to the anode without the use of a hole-transport layer and a hole-injection layer.

31. Organic electroluminescent element according to claim 6, wherein
X is on each occurrence P or As;
Y is on each occurrence S or Se;
Ar is on each occurrence, identically or differently, an aromatic or heteroaromatic ring system having 3 to 60 C atoms, which may be substituted by F or aromatic ring system having 6 to 40 C atoms.
